(19) United States
(12) Patent Application Publication
(10) Pub. No.: US 2014/0311569 A1
(43) Pub. Date: Oct. 23, 2014

(54) SOLAR CELL WITH OMNIDIRECTIONAL ANTI-REFLECTION STRUCTURE AND METHOD FOR FABRICATING THE SAME

(71) Applicant: Huey-Liang Hwang, (US)

(72) Inventors: Chun-Heng Chen, Hsinchu (TW); Huey-Liang Hwang, Hsinchu (TW); Jian-Yang Lin, Douliu City (TW); Pi-Chun Juan, New Taipei City (TW); Kuei-Shu Chang-Liao, Hsinchu (TW)

(73) Assignee: Huey-Liang Hwang, Hsinchu (TW)

(21) Appl. No.: 13/868,890

(22) Filed: Apr. 23, 2013

(51) Int. Cl. H01L 31/052; H01L 31/18

(52) U.S. Cl. CPC H01L 31/0527; H01L 31/18
USPC 136/259; 438/72

(57) ABSTRACT

A solar cell with an omnidirectional anti-reflection structure comprises a solar cell substrate, a transparent electric-conduction layer formed on one surface of the solar cell substrate, a plurality of microspheres formed on the transparent electric-conduction layer, and a dielectric layer. The microspheres have a diameter of 0.1-100 μm. The dielectric layer is formed among the microspheres, and covers the surface of the transparent electric-conduction layer without the microspheres and has a thickness smaller than the diameter of the microspheres. Thus, the above-mentioned structure can enhance the absorption of the short-wavelength spectrum and increase the short-circuit current. Further, the structure with the microspheres is adaptable to the omnidirectional light absorption at various incident angles.

### FIELD OF TUE INVENTION

The present invention relates to a solar cell, particularly to a solar cell with an omnidirectional anti-reflection structure and a method for fabricating the same.

### BACKGROUND OF THE INVENTION

Power shortage drives many nations to develop various substitute energies, especially solar energy. Solar energy is easy to access and pollution-free. Besides, solar cells are noiseless and have a long service life. Therefore, much money has been invested in research of solar energy. Recently, many technologies have been developed to improve the utilization efficiency of incident light, including changing the material of interface to promote the photoelectric conversion efficiency; roughening the surface or arranging an anti-reflection layer to reduce reflection.

The surface of a solar cell is normally etched to form a rugged anti-reflection layer to reduce reflection of incident light. If the surface is etched with an isotropic etching technology, the rugged surface is likely to be a regular senate surface or a waved surface. In such a case, the anti-reflection capability is not omnidirectional but poor in some angles.

In some cases, a transparent electric-conduction material is applied to the anti-reflection structure. However, the problems of carrier mobility and interface material between the transparent electric-conduction material and the substrate need improving to increase the photoelectric conversion efficiency. Besides, the matching between the solar cell and the anti-reflection layer also needs improving.

### SUMMARY OF THE INVENTION

One objective of the present invention is to overcome the problem that the conventional solar cell lacks omnidirectional anti-reflection capability.

Another objective of the present invention is to increase the light absorption efficiency of the solar cell and promote the overall photoelectric conversion performance of the solar cell.

To achieve the above-mentioned objectives, the present invention proposes a solar cell with an omnidirectional anti-reflection structure, which comprises a solar cell substrate, a transparent electric-conduction layer formed on one surface of the solar cell substrate, a plurality of microspheres formed on the transparent electric-conduction layer, and a dielectric layer. The microspheres have a diameter of 0.1-100 μm. The dielectric layer is formed among the microspheres, and covers the surface of the transparent electric-conduction layer without the microspheres, and has a thickness smaller than the diameter of the microspheres.

The present invention also proposes a method for fabricating a solar cell with an omnidirectional anti-reflection structure, which comprises

Step S1: fabricating a solar cell substrate;

Step S2: forming a transparent electric-conduction layer on one surface of the solar cell substrate;

Step S3: mixing a plurality of microspheres with a volatile solution to form a mixture solution, and spraying the mixture solution on the transparent electric-conduction layer to make the microspheres be formed on the transparent electric-conduction layer, wherein the microspheres have a diameter of 0.1-100 μm; and

Step S4: using a spin-coating method to coat a dielectric material on the transparent electric-conduction layer to form a dielectric layer formed among the microspheres, and covering the surface of the transparent electric-conduction layer without the microspheres, and having a thickness smaller than the diameter of the microspheres.

In summary, the present invention uses microspheres and a dielectric layer to form an omnidirectional anti-reflection structure to increase the efficiency of incident light utilization and the efficiency of photoelectric conversion.

### BRIEF DESCRIPTION OF THE DRAWINGS

FIGS. 1A-1C are diagrams schematically showing the process of a method for fabricating a solar cell with an omnidirectional anti-reflection structure according to one embodiment of the present invention;

FIG. 2 shows a comparison of the voltage-current conversion efficiencies;

FIG. 3 shows a comparison of external quantum efficiencies;

FIG. 4 shows a comparison of reflectivities;

FIG. 5 shows relationships between the incident angle and the fill factor;

FIG. 6 shows relationships between the incident angle and the open-circuit voltage;

FIG. 7 shows relationships between the incident angle and the short-circuit current density; and

FIG. 8 shows relationships between the incident angle and the conversion efficiency.

### DETAILED DESCRIPTION OF THE PREFERRED EMBODIMENTS

The technical contents of the present invention will be described in detail in cooperation with drawings below.

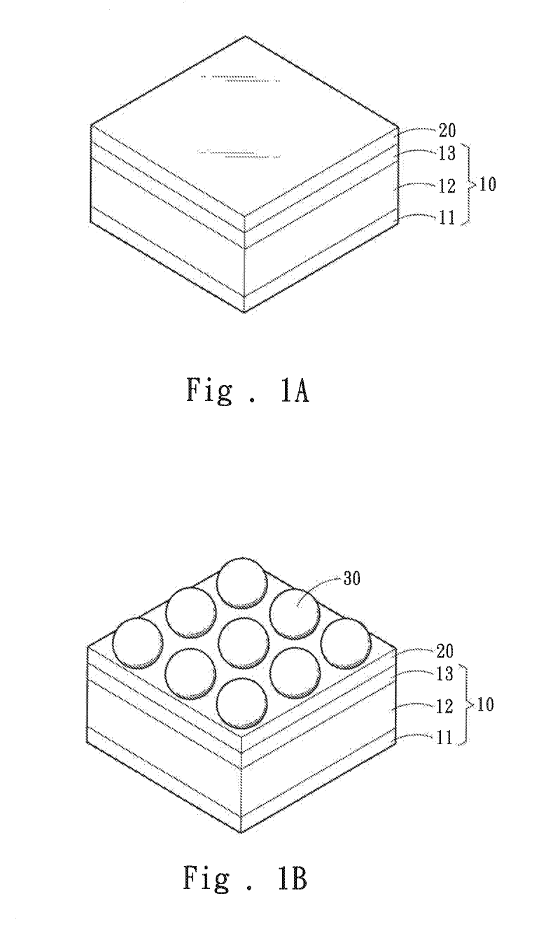

Refer to FIGS. 1A-1C. The present invention proposes a solar cell with an omnidirectional anti-reflection structure, which comprises a solar cell substrate 10, a transparent electric-conduction layer 20 formed on one surface of the solar cell substrate 10, a plurality of microspheres 30 formed on the transparent electric-conduction layer 20, and a dielectric layer 40. The solar cell substrate 10 includes a bottom electrode 11 far away from the transparent electric-conduction layer 20, a P-type semiconductor layer 12, and an N-type semiconductor layer 13 neighboring the transparent electric-conduction layer 20, which are arranged in sequence. In one embodiment, the solar cell substrate 10 also includes an intrinsic semiconductor layer (not shown in the drawings) arranged between the P-type semiconductor layer 12 and the N-type semiconductor layer 13. As the present invention is not focused on the solar cell substrate 10, the specification will not describe the solar cell substrate 10 in further detail.

In one embodiment, the transparent electric-conduction layer 20 is made of indium tin oxide (ITO). In one embodiment, the microspheres 30 are made of a material selected from a group consisting of silicon dioxide, silicon nitride, and aluminum oxide. The microspheres 30 have a diameter of 0.1-100 μm. The dielectric layer 40 is formed among the microspheres 30 and covers the surface of the transparent electric-conduction layer 20 without the microspheres 30. The diameter of the microspheres 30 is greater than the thicknesses of the dielectric layer 40. Thereby, the microspheres 30 protrude from the dielectric layer 40 and cooperate with the dielectric layer 40 to form an omnidirectional anti-reflection structure.

The present invention also proposes a method for fabricating a solar cell with an omnidirectional anti-reflection structure, which comprises the steps as follows.

Step S1—fabricating a solar cell substrate 10: Firstly, wash a P-type semiconductor layer 12 via an RCA (Radio Corporation of America) clean method. Next, dope N-type ions into the P-type semiconductor layer 12 to form an N-type semiconductor layer 13. In one embodiment, an intrinsic semiconductor material is formed between the P-type semiconductor layer 12 and the N-type semiconductor layer 13 to increase the photoelectric conversion efficiency. In one embodiment, boron ion is diffused into the bottom of the P-type semiconductor layer 12 to form a back surface field. In one embodiment, a P-type ion, is doped into an N-type semiconductor material to form the P-type semiconductor layer 12. The fabrication of the solar cell substrate 10 can be undertaken in different ways, depending on the requirements. The embodiments described above are only to exemplify the methods for fabricating the solar cell substrate 10. The present invention does not constrain the material, structure and fabrication method of the solar cell substrate 10. As the present invention is not focused on the solar cell substrate 10, the specification will not describe the method for fabricating the solar cell substrate 10 in further detail.

Step S1A—deoxidizing with hydrogen chloride: Soak the solar cell substrate 10 in a hydrochloric acid solution containing 99 wt % hydrochloric acid for ten minutes to remove the silicon dioxide on the surface of the solar cell substrate 10 and reduce interface mismatch between the solar cell substrate 10 and another material.

Step S2—forming a transparent electric-conduction layer 20 on one surface of the solar cell substrate 10, as shown in FIG. 1A. In one embodiment, the transparent electric-conduction layer 20 is made of ITO (Indium Tin Oxide). In one embodiment, the transparent electric-conduction layer 20 has a thickness of 60 nm. Owing to Step S1A, there is less mismatch between the transparent electric-conduction layer 20 and the solar cell substrate 10. Therefore is lowered the energy barrier and increased the electric conductivity and short-circuit current.

Step S2A—annealing: Anneal the solar cell substrate 10 at a temperature of 250-350° C. for 30 minutes to homogenize the transparent electric-conduction layer 20 and make the transparent electric-conduction layer 20 attached to the surface of the solar cell substrate 10.

Step S3—mixing a plurality of microspheres 30 with a volatile solution to form a mixture solution, and spraying the mixture solution on the transparent electric-conduction layer 20 to make the microspheres 30 be formed on the transparent electric-conduction layer 20, as shown in FIG. 1B. The microspheres 30 have a diameter of 0.1-100 μm. In one embodiment, the volatile solution is a solution containing over 0.2 wt % methanol. In one embodiment, the mixture solution is filled into an ultrasonic sprayer, and the ultrasonic sprayer sprays the mixture solution on the surface of the transparent electric-conduction layer 20.

Step S3A—heating and evaporating: Heat the solar cell substrate 10 to a temperature of 80-110° to make the volatile solution evaporate faster with the microspheres 30 left on the surface of the transparent electric-conduction layer 20.

Step S4—using a spin-coating method to coat an SOD (Spin on Dielectric) material on the transparent electric-conduction layer 20 to form a dielectric layer 40, as shown in FIG. 1C. The dielectric layer 40 is formed among the microspheres 30 and covers the surface of the transparent electric-conduction layer 20 without the microspheres 30. The diameter of the microspheres 30 is greater than the thicknesses of the dielectric layer 40.

Step S5—using an electron beam vapor deposition method to form a front-side electrode and a back-side electrode 11, wherein the front-side electrode is electrically connected with the transparent electric-conduction layer 20, and wherein the back-side electrode 11 is formed on one surface of the solar cell substrate 10, which is far away from the transparent electric-conduction layer 20.

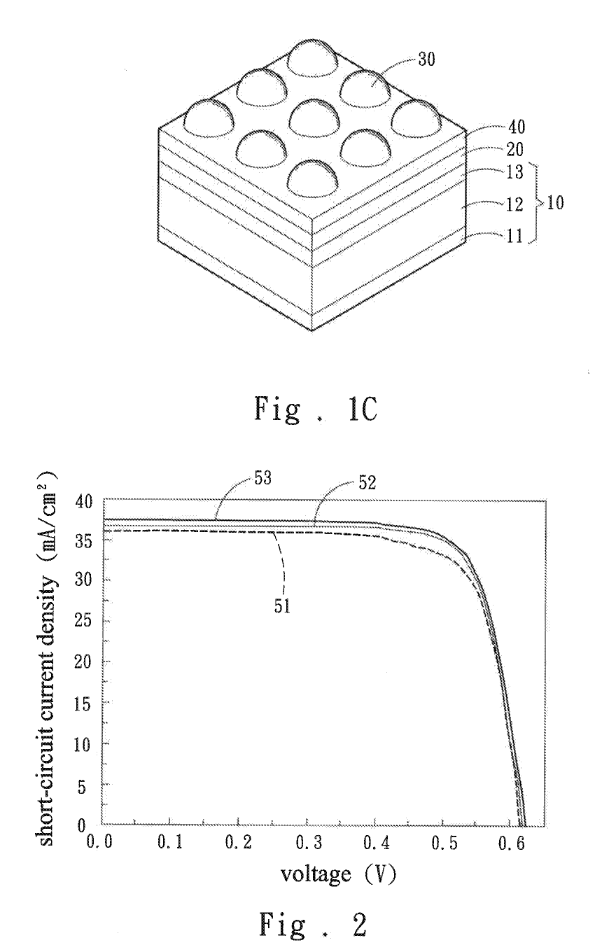

Refer to FIG. 2 for the comparison of the conversion efficiencies of the voltage and the short-circuit current density, wherein Curve 51, Curve 52 and Curve 53 respectively express the conventional technology, a first embodiment and a second embodiment. In the conventional technology, silicon nitride (SiNx) is etched with a KOH solution to roughen the surface and form an ARC (Anti-Reflection Coating) structure. In the first embodiment, the solar cell with the omnidirectional anti-reflection structure of the present invention is not processed with HCl. In the second embodiment, the solar cell with the omnidirectional anti-reflection structure of the present invention is processed with HCl. In FIG. 2, the second embodiment (Curve 53) has the highest voltage-current conversion efficiency; the conventional technology (Curve 51) has the lowest voltage-current conversion efficiency; the first embodiment (Curve 52) has the medium voltage-current efficiency Therefore, it is proved: the present invention has higher conversion efficiency, especially the second embodiment (Curve 53) wherein the oxide in the interface is processed with HCl.

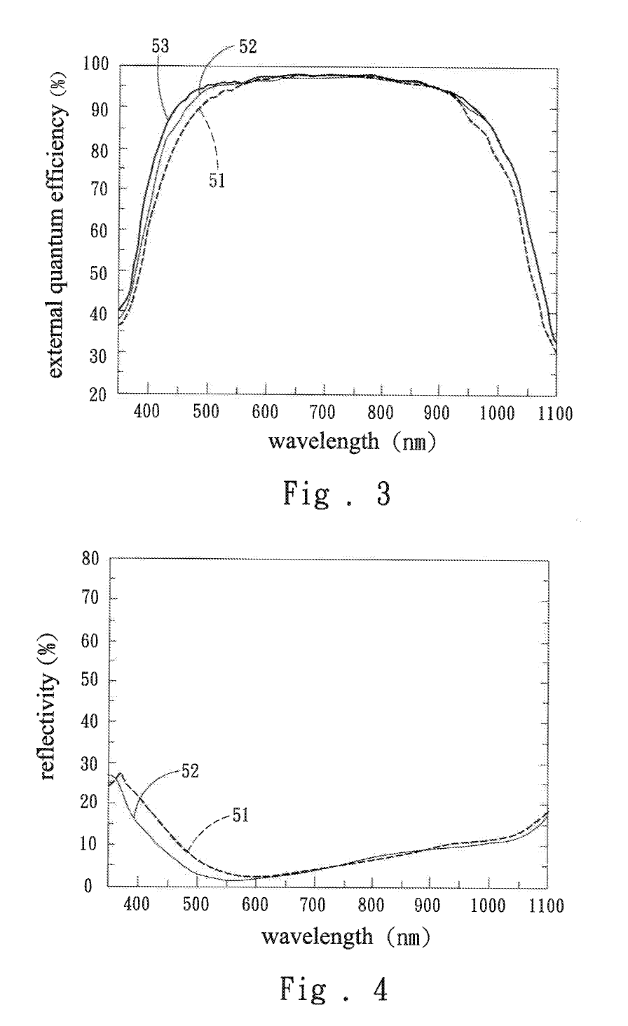

Refer to FIG. 3 for the comparison of EQE (External Quantum Efficiency). In FIG. 3, the second embodiment (Curve 53) has the highest EQE in the range of short wavelengths and long wavelengths; the conventional technology (Curve 51) has the lowest EQE; the first embodiment (Curve 52) has the medium EQE. Therefore, it is proved: the structure and method of the present invention can achieve better efficiency. FIG. 3 shows that the present invention has higher EQE in the wavelength range of 400-600 nm. Thus, the present invention achieves higher absorption efficiency and increases the short-circuit current density in the short-wavelength spectrum. Refer to FIG. 4 for the reflectivities. FIG. 4 shows that the first embodiment (Curve 52) has a lower reflectivity than the conventional technology (Curve 51).

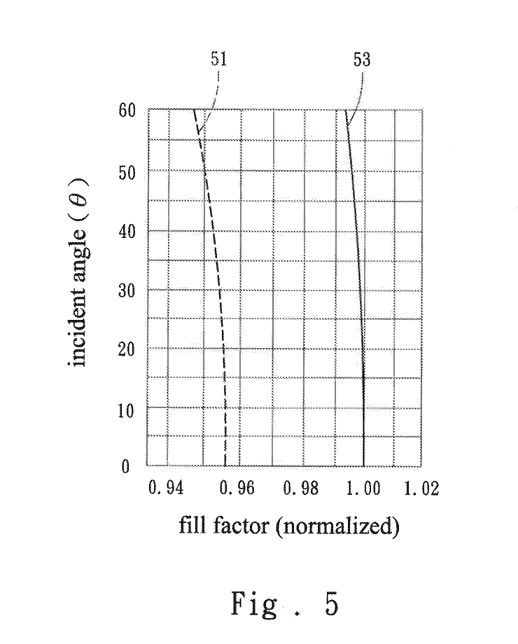

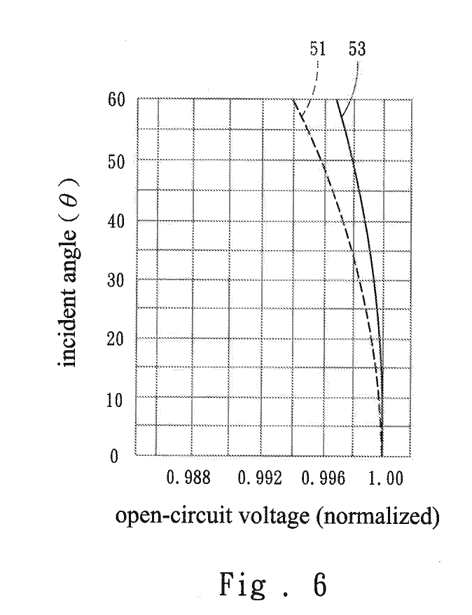

Refer to FIG. 5 for the relationships between the incident angle and the fill factor. In FIG. 5, the normalized fill factor is used as the horizontal axis. The fill factor expresses the electric conductivity of the structure. The higher the fill factor, the better the electric conductivity. FIG. 5 shows that the second embodiment (Curve 53) is about 4.5% better than the conventional technology (Curve 51). Refer to FIG. 6 for the relationships between the incident angle and the open-circuit voltage. In FIG. 6, the normalized open-circuit voltage is used as the horizontal axis. At an incident angle of 60 degrees, the second embodiment (Curve 53) is 0.3% better than the conventional technology (Curve 51) in the open-circuit voltage. With increase of the incident angle, Curve 51 is deflected to a greater extent than Curve 53 in FIG. 6. It means that the increasing incident angle decreases the open-circuit voltage of the conventional technology (Curve 51) more rapidly. In other words, the increasing incident angle decreases the open-circuit voltage of the second embodiment (Curve 53) relatively slightly. Therefore, it proves that the anti-reflection structure of the present invention can enhance omnidirectional light absorption.

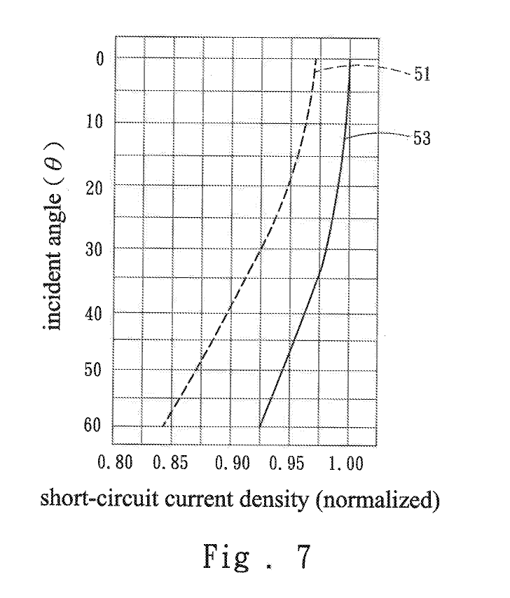

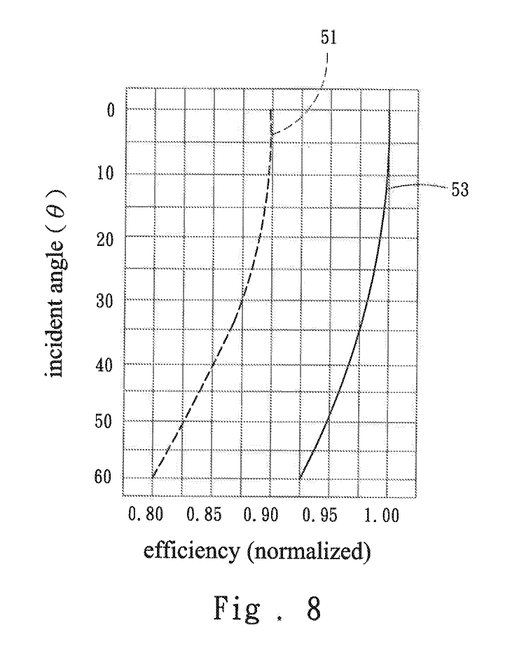

Refer to FIG. 7 for the relationships between the incident angle and the short-circuit current density. In FIG. 7, the normalized short-circuit current density is used as the horizontal axis. At an incident angle of 0 degree, the short-circuit current density of the second embodiment (Curve 53) is 3.1% higher than the conventional technology (Curve 51). At an incident angle of 60 degrees, the short-circuit current density of the second embodiment (Curve 53) is 9.6% higher than the conventional technology (Curve 51). FIG. 7 shows that the variation of the incident angle causes smaller deflection in Curve 53 (the second embodiment) than in Curve 51 (the conventional technology). In other words, the present invention is less likely to be influenced by the variation of the incident angle. Refer to FIG. 8 for the relationships between the incident angle and the conversion efficiency. At an incident angle of 0 degree, the conversion efficiency of the second embodiment (Curve 53) is 7.4% higher than the conventional technology (Curve 51). At an incident angle of 60 degrees, the conversion efficiency of the second embodiment (Curve 53) is 13.5% higher than the conventional technology (Curve 51). FIG. 8 also shows that the variation of the incident angle causes smaller deflection in Curve 53 (the second embodiment) than in Curve 51 (the conventional technology) and that the present invention is less likely to be influenced by the variation of the incident angle.

In conclusion, the present invention is characterized in
1. The present invention uses the microspheres and the dielectric layer to form the omnidirectional anti-reflection structure, which is can effectively increase the utilization efficiency of incident light and promote the photoelectric conversion efficiency;
2. The present invention uses a hydrochloric acid treatment to remove the oxide interface of the solar cell substrate and homogenize the electric conductivity of the interface between the solar cell substrate and the transparent electric-conduction layer, whereby is promoted the overall efficiency of the solar cell;
3. The present invention is less likely to be influenced by the variation of the incident angle and able to undertake photoelectric conversion stably under the variation of the incident angle; and
4. The present invention has higher photoelectric conversion efficiency in the short-wavelength spectrum (400-600 nm)

The present invention is proved to possess utility, novelty and non-obviousness and meet the condition for a patent. Thus, the Inventors file the application for a patent. It is appreciated if the patent is approved fast.

What is claimed is:

1. A solar cell with an omnidirectional anti-reflection structure, comprising:
a solar cell substrate;
a transparent electric-conduction layer formed on one surface of the solar cell substrate;
a plurality of microspheres formed on the transparent electric-conduction layer and having a diameter of 0.1-100 μm; and
a dielectric layer formed among the microspheres, and covering the surface of the transparent electric-conduction layer without the microspheres, and having a thickness smaller than the diameter of the microspheres.

2. The solar cell with the omnidirectional anti-reflection structure according to claim 1, wherein the solar cell substrate includes a bottom electrode far away from the transparent electric-conduction layer, a P-type semiconductor layer, and an N-type semiconductor layer neighboring the transparent electric-conduction layer, which are arranged in sequence.

3. The solar cell with the omnidirectional anti-reflection structure according to claim 1, wherein the transparent electric-conduction layer is made of indium tin oxide (ITO).

4. The solar cell with the omnidirectional anti-reflection structure according to claim 1, wherein the microspheres are made of a material selected from a group consisting of silicon dioxide, silicon nitride, and aluminum oxide.

5. A method for fabricating a solar cell with an omnidirectional anti-reflection structure, comprising the steps of:
Step S1: fabricating a solar cell substrate;
Step S2: forming a transparent electric-conduction layer on one surface of the solar cell substrate;
Step S3: mixing a plurality of microspheres with a volatile solution to form a mixture solution, and spraying the mixture solution on the transparent electric-conduction layer to make the microspheres be formed on the transparent electric-conduction layer, wherein the microspheres have a diameter of 0.1-100 μm;
Step S4: using a spin-coating method to coat a dielectric material on the transparent electric-conduction layer to form a dielectric layer among the microspheres and covering the surface of the transparent electric-conduction layer without the microspheres, wherein the diameter of the microspheres is greater than the thicknesses of the dielectric layer.

6. The method for fabricating the solar cell with the omnidirectional anti-reflection structure according to claim 5, wherein in the Step S1, N-type ions are doped into a P-type semiconductor layer to form an N-type semiconductor layer.

7. The method for fabricating the solar cell with the omnidirectional anti-reflection structure according to claim 5 further comprising a Step S1A: soaking the solar cell substrate in a hydrochloric acid solution, which is interposed between the Step S1 and the Step S2.

8. The method for fabricating the solar cell with the omnidirectional anti-reflection structure according to claim 5 further comprising a Step S2A: annealing the solar cell substrate at a temperature of 250-350° C., which is interposed between the Step S2 and the Step S3.

9. The method for fabricating the solar cell with the omnidirectional anti-reflection structure according to claim 5 further comprising a Step S3A: heating the solar cell substrate to a temperature of 80-110° C. to evaporate the volatile solution, which is interposed between the Step S3 and the Step S4.

10. The method for fabricating the solar cell with the omnidirectional anti-reflection structure according to claim 5 further comprising a Step S5: using an electron beam vapor deposition method to form a front-side electrode and a back-side electrode, which succeeds to the Step S4, and wherein the front-side electrode is electrically connected with the transparent electric-conduction layer, and wherein the back-side electrode is formed on one surface of the solar cell substrate, which is far away from the transparent electric-conduction layer.

11. The method for fabricating the solar cell with the omnidirectional anti-reflection structure according to claim 5, wherein the transparent electric-conduction layer is made of indium tin oxide (ITO).

12. The method for fabricating the solar cell with the omnidirectional anti-reflection structure according to claim 5, wherein the microspheres are made of a material selected from a group consisting of silicon dioxide, silicon nitride, and aluminum oxide.
